(19) United States
(12) Patent Application Publication
(10) Pub. No.: US 2014/0191205 A1
(43) Pub. Date: Jul. 10, 2014

(54) BIPOLAR COMPOUND AND ORGANIC ELECTROLUMINESCENT DEVICE EMPLOYING THE SAME

(71) Applicant: Industrial Technology Research Institute, Chu-Tung (TW)

(72) Inventors: Chin-Hsien CHEN, New Taipei City (TW); Lun-Chia HSU, Hemei Township (TW); Chien-Hong CHENG, Hsinchu City (TW)

(21) Appl. No.: 13/935,170

(22) Filed: Jul. 3, 2013

(30) Foreign Application Priority Data
Jan. 8, 2013 (TW) 102100572

(51) Int. Cl. H01L 51/00

(52) U.S. Cl. CPC H01L 51/0072
USPC 257/40; 546/173; 546/167

(57) ABSTRACT

The present disclosure relates to a bipolar compound represented by the following formula (I); and an organic luminescent diode device containing the same.

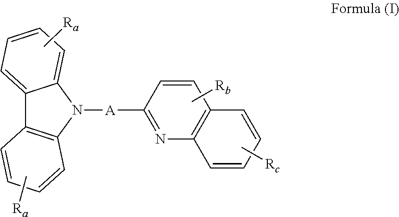

wherein A represents a phenyl, a biphenyl, or a terphenyl group; and
Rₐ, R_{b}, and R_{c} are independently selected from a group consisting of a hydrogen, a halo, a cyano, a trifluoromethyl, an amino, a C₁-C₁₀ alkyl, a C₂-C₁₀ alkenyl, a C₂-C₁₀ alkynyl, a C₃-C₂₀ cycloalkyl, a C₃-C₂₀ cycloalkenyl, a C₁-C₂₀ heterocyclic alkyl, a C₁-C₂₀ hetercyclic alkenyl, an aryl, and a heteroaryl groups.

This application claims the benefit of Taiwan application Serial No. 102100572, filed Jan. 8, 2013, the disclosure of which is incorporated by reference herein in its entirety.

### TECHNICAL FIELD

The present disclosure relates to a bipolar compound and an organic electroluminescent device employing the same.

### BACKGROUND

Organic electroluminescence is a self luminescent phenomenon, such a luminescent phenomenon occurs due to that organic compounds excited by electric energy generated from applying electric field and thus emits light. Recently, the development for organic electroluminescence has increased rapidly and thus the industries in this filed invest their money in production of organic luminescent diode aggressively. The principle for organic luminescent diode is similar to that for inorganic luminescent diode, which generally classifies into two classes, i.e. small molecular organic luminescent diode and macro molecular organic luminescent diode. Among them, the small molecular organic luminescent diode uses small molecular dye or pigment as a host material while macro molecular organic luminescent diode uses conjugate polymer as a host material.

The critical point to produce excellent organic luminescent diode is the material constituting diode, especial the emission material used in emission layer. A useful emission material should satisfy the following conditions: (1) it possesses fluorescence with high quantum efficiency and its fluorescence spectrum mainly distributes in visible region of from 400˜700 nm; (2) it has excellent semi-conductance, high electric conductivity, is capable of transporting electron or hole, or both; (3) it is easily formed into film without occurring pin-hole in the film in several tens thickness; and (4) it possesses thermal stability.

In production of organic luminescent diode, the emission material is critical, especial host emission material. The host emission material should exhibit properties of quickly capturing carriers, energy transition, high glass transition temperature, high thermal stability, suitable singlet and triplet energy gap. Furthermore, in addition to the luminescent efficiency, another requirement for emission material is its life time. Thus there is still a room for developing host emission material in organic luminescent diode.

### SUMMARY

The present disclosure provides a bipolar compound represented by the following formula (I):

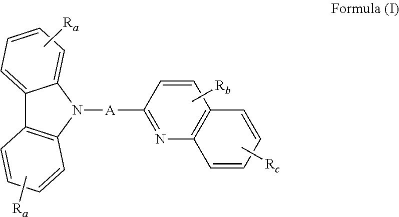

wherein A represents a phenyl, biphenyl, or terphenyl group; and
Rₐ, R_{b}, and R_{c} are independently selected from a group consisting of hydrogen, halo, cyano, trifluoromethyl, amino, C₁-C₁₀ alkyl, C₂-C₁₀ alkenyl, C₂-C₁₀ alkynyl, C₃-C₂₀ cycloalkyl, C₃-C₂₀ cycloalkenyl, C₁-C₂₀ heterocyclic alkyl, C₁-C₂₀ hetercyclic alkenyl, aryl, and heteroaryl group.

The present disclosure also provides an organic luminescent diode device comprising a pair of electrodes; and an electroluminescent element disposed between said pair of electrodes; wherein said electroluminescent element containing a compound having the following formula (I):

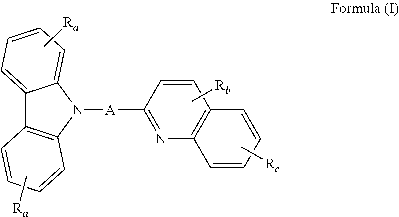

wherein all symbols are defined the same as the above.

The present disclosure also provides an organic electroluminescent diode device comprising a pair of electrodes; and an electroluminescent element disposed between said pair of electrodes; wherein said electroluminescent element comprises an emission layer and said emission layer comprises a dopant material and a compound having the following formula (I) as a host material:

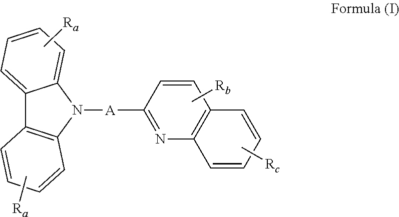

wherein all symbols are defined the same as the above.

### BRIEF DESCRIPTION OF DRAWINGS

The disclosure may be more completely understood in consideration of the following detailed description of various embodiments of the disclosure in connection with the accompanying drawings

FIG. 1 is a schematic diagram showing an organic luminescent diode device containing the present compound.

FIG. 2 is a graph showing the luminescent efficiency of devices A, E, H, I with time.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The present disclosure provides a bipolar compound represented by the following formula (I):

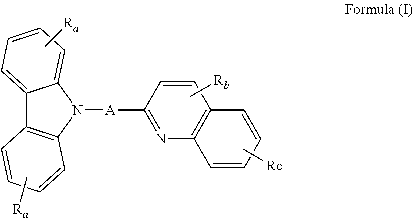

wherein A represents phenyl, biphenyl, or terphenyl group; and Rₐ, R_{b}, and R_{c} are independently selected from a group consisting of hydrogen, halo, cyano, trifluoromethyl, amino, C₁-C₁₀ alkyl, C₂-C₁₀ alkenyl, C₂-C₁₀ alkynyl, C₃-C₂₀ cycloalkyl, C₃-C₂₀ cycloalkenyl, C₁-C₂₀ heterocyclic alkyl, C₁-C₂₀ hetercyclic alkenyl, aryl, and heteroaryl group.

In one embodiment, the A is further substituted by at least one substituent selected from a group consisting of hydrogen, halo, cyano, trifluoromethyl, amino, C₁-C₁₀ alkyl, C₂-C₁₀ alkenyl, C₂-C₁₀ alkynyl, C₃-C₂₀ cycloalkyl, C₃-C₂₀ cycloalkenyl, C₁-C₂₀ heterocyclic alkyl, C₁-C₂₀ hetercyclic alkenyl, aryl, and heteroaryl groups.

In one embodiment, the aryl is a phenyl group or a substituted phenyl group. The term “substituted phenyl group” means phenyl group which is substituted by substitutent(s), such as halogen, alkyl, alkylphenyl, or heteroaryl group, and the like, but the substituents are not limited in the list.

In one embodiment, the heteroaryl may be, but not limited to, carbazolyl group.

In one embodiment, the Rₐ and R_{c} are different by each other.

In one embodiment, the Rₐ and R_{c} are independently selected from the following groups:

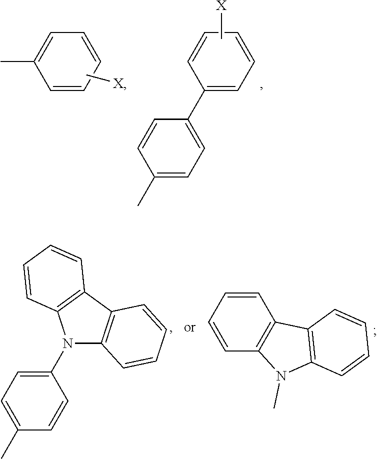

wherein X represents hydrogen, halo, cyano, trifluoromethyl, amino, or C₁-C₁₀ alkyl group, but are not limited in the list.

The present disclosure also provides an organic luminescent diode device comprising a pair of electrodes; and an organic luminescent unit positioned between said pair of electrodes; wherein said organic luminescent unit containing a compound having the following formula (I):

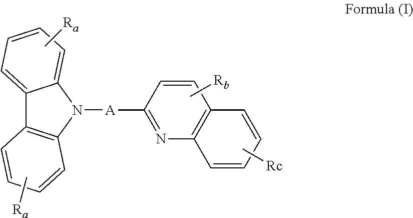

wherein all symbols are defined the same as the above.

The present disclosure also provides an organic electroluminescent diode device comprising a pair of electrodes; and an organic luminescent unit positioned between said pair of electrodes; wherein said organic luminescent unit comprising a luminescent layer containing a dopant material and a compound having the following formula (I) as a host material:

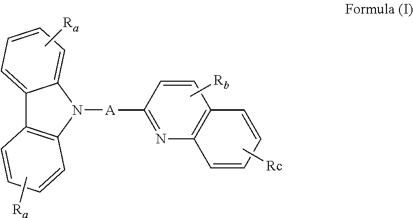

wherein all symbols are defined the same as the above.

In one embodiment, the dopant material in the luminescent layer may comprise a green emitting dopant material in an amount of from 0 to 10 wt. %. In the embodiment, the green emitting dopant material may be, but not limited to, tris(2-phenylpyridine)iridium (Ir(ppy)₃).

In one embodiment, the dopant material in the luminescent layer may comprise an orange emitting dopant material in an amount of from 0 to 10 wt. %. In the embodiment, the orange emitting dopant material may be, but not limited to, tris(2-phenylquinoline)iridium (Ir(pq)₃).

In one embodiment, the dopant material in the luminescent layer may comprise a red emitting dopant material in an amount of from 0 to 10 wt. %. In the embodiment, the red emitting dopant material may be, but not limited to, tris(2-phenyl-isoquinoline)iridium (Ir(piq)₃).

### A. Synthesis of the Present Compound

The compound having a quinolyl and carbazolyl groups of the present disclosure is synthesized, e.g. through the following scheme.

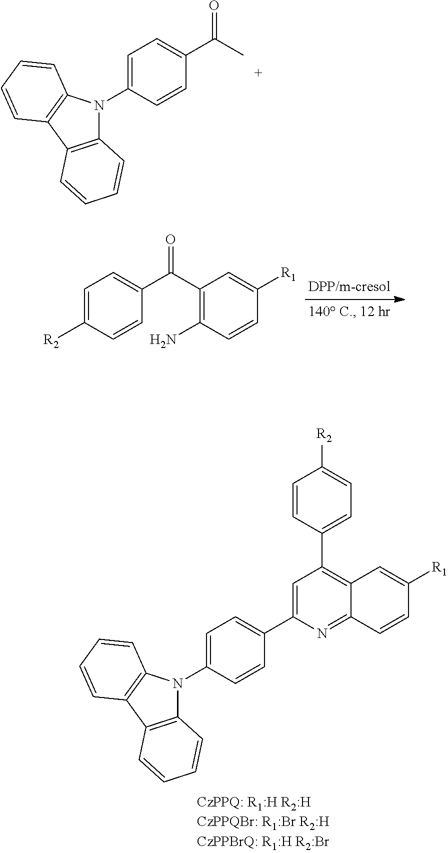

CzPPQ derivatives are produced by reacting 1-(4-(9H-carbazol-9-yl)phenyl)-ethanone and 2-aminobenzophenone in the presence of diphenyl phosphate and m-cresol at a temperature of 140° C. The other compounds having a quinolyl and a carbazolyl groups are produced by using appropriate starting materials.

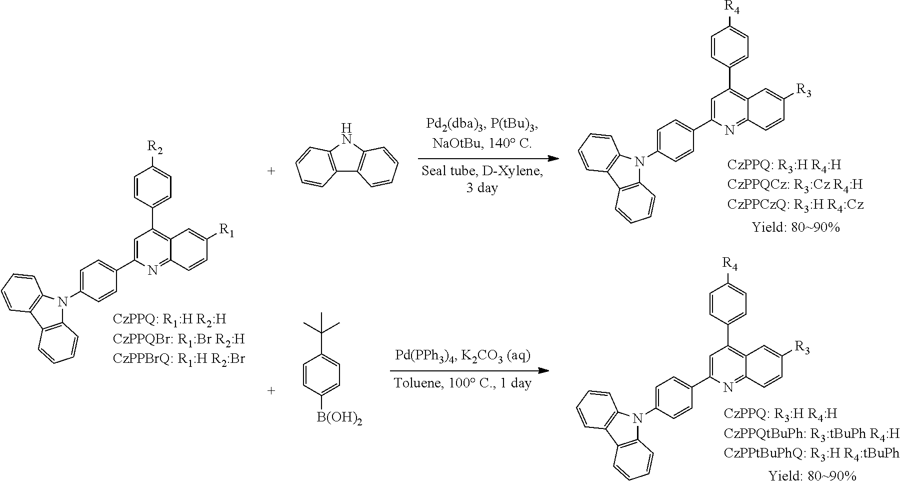

### Preparation Example 1

### Preparation of 9-(4-(4-phenylquinolin-2-yl)phenyl)-9H-carbazole (CzPPQ)

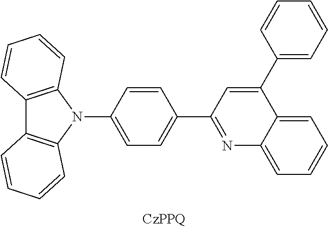 [SMILES: c1ccc(-c2cc(-c3ccc(-n4c5ccccc5c5ccccc54)cc3)nc3ccccc23)cc1]

1-(4-(9H-carbazol-9-yl)phenyl)-ethanone (285 mg, 1.00 mmol), 2-aminobenzo-phenone (400 mg, 2.00 mmol), diphenyl phosphate (DPP) (751 mg, 3.00 mmol), and as-distilled m-cresol (1.0 mL) were added into a round-bottom flask and reacted under nitrogen atmosphere with heating to a temperature 140° C. for 12 hours. When the reaction completed, the resultant mixture was added with 10 wt. % triethylamine/methanol and then the precipitate was filtered out and purified by column chromatography using hexane/ethyl acetate in volume ratio of 10:1 to obtain 381 mg of 9-(4-(4-phenylquinolin-2-yl)phenyl)-9H-carbazole, yield=85.4%.

The NMR data of the product was as follows.

¹H NMR (400 MHz, CDCl₃, δ): 7.31 (dd, 2H, J=7.6, 7.2 Hz), 7.44 (dd, 2H, J=8.0, 7.6 Hz), 7.50-7.62 (m, 8H), 7.73-7.80 (m, 3H), 7.91 (s, 1H), 7.95 (d, 1H, J=8.4 Hz), 8.16 (d, 2H, J=7.6 Hz), 8.30 (d, 1H, J=8.4 Hz), 8.43 (d, 2H, J=8.4 Hz); ¹³C NMR (100 MHz, CDCl₃, δ): 109.8, 119.1, 120.1, 120.3, 123.5, 125.7, 125.8, 126.0, 126.5, 127.2, 128.5, 128.6, 129.0, 129.5, 129.7, 130.1, 138.2, 138.5, 138.7, 140.6, 148.8, 149.4, 155.9; HRMS (EI, m/z): [M⁺] calcd for C₃₃H₂₂N₂, 446.1783. found, 446.1779. Anal. calcd. for C₃₃H₂₂N₂: C, 88.76; H, 4.97; N, 6.27. found: C, 88.49; H, 4.87; N, 6.35.

### Preparation Example 2

### Preparation of 9-(4-(4-(4-bromophenyl)quinolin-2-yl)phenyl)-9H-carbazole (CzPPBrQ)

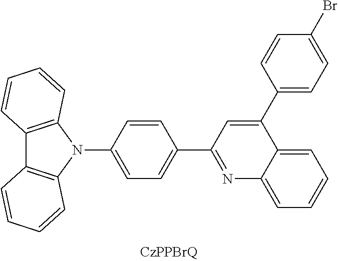 [SMILES: Brc1ccc(-c2cc(-c3ccc(-n4c5ccccc5c5ccccc54)cc3)nc3ccccc23)cc1]

1-(4-(9H-carbazol-9-yl)phenyl)ethanone (285 mg, 1.00 mmol), (2-aminophenyl) (4-bromophenyl-methanone (553 mg, 2.00 mmol), diphenyl phosphate (DPP) (751 mg, 3.00 mmol), and as-distilled m-cresol (1.0 mL) were added into a round-bottom flask and reacted under nitrogen atmosphere with heating to a temperature 140° C. for 12 hours. When the reaction completed, the resultant mixture was added with 10 wt. % triethylamine/methanol and then the precipitate was filtered out and purified by column chromatography using hexane/ethyl acetate in volume ratio of 10:1 to obtain 426 mg of 9-(4-(4-(4-bromo-phenyl)quinolin-2-yl)phenyl)-9H-carbazole, yield=81.2%.

The NMR data of the product was as follows.

¹H NMR (400 MHz, CDCl₃, δ): 7.30 (dd, 2H, J=7.2, 7.2 Hz), 7.40-7.52 (m, 7H), 7.69-7.80 (m, 7H), 7.86-7.88 (m, 2H), 8.14 (d, 2H, J=7.2 Hz), 8.27 (d, 1H, J=8.8 Hz), 8.41 (d, 2H, J=8.4 Hz); ¹³C NMR (100 MHz, CDCl₃, δ): 109.8, 119.0, 120.1, 120.4, 122.9, 123.6, 125.3, 125.5, 126.0, 126.8, 127.3, 129.1, 129.9, 130.3, 131.2, 131.9, 137.2, 138.4, 138.9, 140.7, 148.2, 148.9, 156.0; HRMS (EI, m/z): [M⁺] calcd for C₃₃H₂₁BrN₂, 524.0888. found, 524.0893.

### Preparation Example 3

### Preparation of 9-(4-(6-bromo-4-phenylquinolin-2-yl)-phenyl)-9H-carbazole (CzPPQBr)

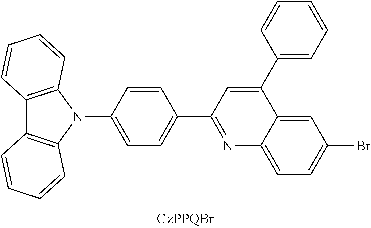 [SMILES: Brc1ccc2nc(-c3ccc(-n4c5ccccc5c5ccccc54)cc3)cc(-c3ccccc3)c2c1]

1-(4-(9H-carbazol-9-yl)phenyl)ethanone (285 mg, 1.00 mmol), (2-amino-5-bromo-phenyl)(phenyl)methanone (553 mg, 2.00 mmol), diphenyl phosphate (DPP) (751 mg, 3.00 mmol), and as-distilled m-cresol (1.0 mL) were added into a round-bottom flask and reacted under nitrogen atmosphere with heating to a temperature 140° C. for 12 hours. When the reaction completed, the resultant mixture was added with 10 wt. % triethylamine/methanol and then the precipitate was filtered out and purified by column chromatography using hexane/ethyl acetate in volume ratio of 10:1 to obtain 437 mg of 9-(4-(6-bromo-4-phenylquinolin-2-yl)phenyl)-9H-carbazole, yield=83.2%.

The NMR data of the product was as follows.

¹H NMR (400 MHz, CDCl₃, δ): 7.30 (ddd, 2H, J=8.0, 7.6, 1.0 Hz), 7.42 (ddd, 2H, J=8.0, 6.8, 1.2 Hz), 7.48-7.50 (m, 2H), 7.55-7.60 (m, 5H), 7.73 (d, 2H, J=8.4 Hz), 7.82 (dd, 1H, J=9.0, 6.2 Hz), 7.91 (s, 1H), 8.07 (d, 1H, J=3.0 Hz), 8.13-8.16 (m, 3H), 8.41 (d, 2H, J=8.4 Hz); ¹³C NMR (100 MHz, CDCl₃, δ): 109.7, 109.8, 119.9, 120.2, 120.4, 120.7, 123.6, 126.4, 127.1, 127.3, 127.9, 128.8, 128.9, 129.1, 129.4, 131.8, 133.3, 137.6, 138.0, 139.1, 140.6, 148.8, 156.2; HRMS (EI, m/z): [M⁺] calcd for C₃₃H₂₁BrN₂, 524.0888. found, 524.0897.

### Preparation Example 4

### Preparation of (9,9′-(quinolin-2,4-diyl)-bis-(4,1-phenylene))-bis(9H-carbazole) (CzPPCzQ)

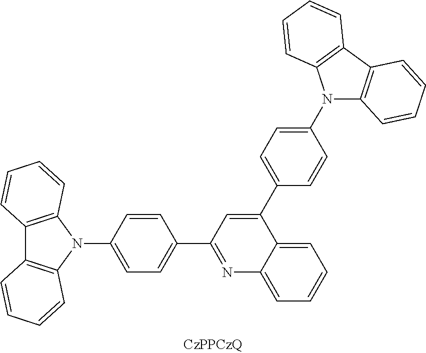 [SMILES: c1ccc2c(-c3ccc(-n4c5ccccc5c5ccccc54)cc3)cc(-c3ccc(-n4c5ccccc5c5ccccc54)cc3)nc2c1]

9-(4-(4-(4-Bromo-phenyl)quinolin-2-yl)phenyl)-9H-carbazole (525 mg, 1.00 mmol), carbazole (200 mg, 1.2 mmol), Pd(dba)₂ (33 mg, 0.060 mmol), tri-tert-butylphosphine (96 mg, 0.048 mmol), sodium tert-butoxide (432 mg, 4.50 mmol) and solvent o-xylene (3.00 mL) were added into a high pressure tube, and reacted and heated at a temperature of 150° C. for 48 hours. When the reaction completed, the resultant mixture was filtered through Celite to remove metal salts and washed with methylene chloride several times. The filtrates were collected and concentrated. The resultant product was purified by column chromatography using hexane/ethyl acetate in volume ratio of 10:1 to obtain 528 mg of (9,9′-(quinolin-2,4-diyl)-bis-(4,1-phenylene))-bis(9H-carbazole), yield=86.3%.

The NMR data of the product was as follows.

¹H NMR (400 MHz, CDCl₃, δ): 7.28-7.33 (m, 4H), 7.39-7.46 (m, 7H), 7.51 (dd, 4H, J=8.0, 8.0 Hz), 7.61 (d, 2H, J=7.2 Hz), 7.78 (d, 2H, J=8.4 Hz), 7.96 (d, 1H, J=8.8 Hz), 8.00 (s, 1H), 8.11-8.18 (m, 5H), 8.47-8.51 (m, 3H); ¹³C NMR (100 MHz, CDCl₃, δ): 109.5, 109.8, 120.0, 120.2, 120.3, 120.3, 120.4, 123.1, 123.5, 123.6, 126.0, 126.1, 126.6, 127.2, 128.9, 129.2, 129.3, 131.7, 135.8, 137.5, 139.2, 140.6, 140.7, 156.2; HRMS (EI, m/z): [M⁺] calcd for C₄₅H₂₉N₃, 611.2361. found, 611.2365. Anal. calcd. for C₄₅H₂₉N₃: C, 88.35; H, 4.78; N, 6.87. found: C, 88.15; H, 4.74; N, 7.02.

### Preparation Example 5

### Preparation of 9-(4-(6-(9H-carbazol-9-yl)-4-phenylquinolin-2-yl)phenyl)-9H-carbazole (CzPPQCz)

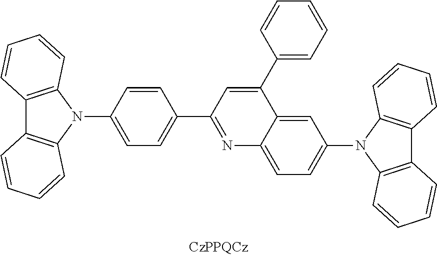 [SMILES: c1ccc(-c2cc(-c3ccc(-n4c5ccccc5c5ccccc54)cc3)nc3ccc(-n4c5ccccc5c5ccccc54)cc23)cc1]

9-(4-(6-Bromo-4-phenylquinolin-2-yl)phenyl)-9H-carbazole (525 mg, 1.00 mmol), carbazole (200 mg, 1.2 mmol), Pd(dba)₂ (33 mg, 0.060 mmol), tri-tert-butylphosphine (96 mg, 0.048 mmol), sodium tert-butoxide (432 mg, 4.50 mmol) and solvent o-xylene (3.00 mL) were added into a high pressure tube, and reacted and heated at a temperature of 150° C. for 48 hours. When the reaction completed, the resultant mixture was filtered through Celite to remove metal salts and washed with methylene chloride several times. The filtrates were collected and concentrated. The resultant product was purified by column chromatography using hexane/ethyl acetate in volume ratio of 10:1 to obtain 524 mg of 9-(4-(6-(9H-carbazol-9-yl)-4-phenylquinolin-2-yl)phenyl)-9H-carbazole, yield=85.7%.

The NMR data of the product was as follows.

1H NMR (400 MHz, CDCl₃, δ): 7.30-7.37 (m, 4H), 7.43-7.54 (m, 6H), 7.58-7.64 (m, 3H), 776-7.87 (m, 7H), 8.03 (s, 1H), 8.10 (d, 1H, J=8.4 Hz), 8.16-8.21 (m, 4H), 8.35 (d, 2H, J=8.8 Hz), 8.48 (d, 2H, J=8.4 Hz); ¹³C NMR (100 MHz, CDCl₃, δ): 109.7, 109.8, 119.3, 120.1, 120.3, 120.4, 120.5, 123.5, 123.6, 125.5, 125.7, 126.0, 126.1, 126.8, 127.1, 127.3, 129.1, 139.9, 130.0, 131.1, 137.2, 138.1, 138.5, 138.9, 14.07, 148.5, 149.0, 156.0; HRMS (EI, m/z): [M⁺] calcd for C₄₅H₂₉N₃, 611.2361. found, 611.2367. Anal. calcd. for C₄₅H₂₉N₃: C, 88.35; H, 4.78; N, 6.87. found: C, 88.25; H, 4.96; N, 6.54.

### Preparation Example 6

### Preparation of 9-(4-(4-(4′-(tert-butyl)-[1,1′-biphenyl]-4-yl)-quinolin-2-yl)phenyl)-9H-carbazol (CzPPtBuPhQ)

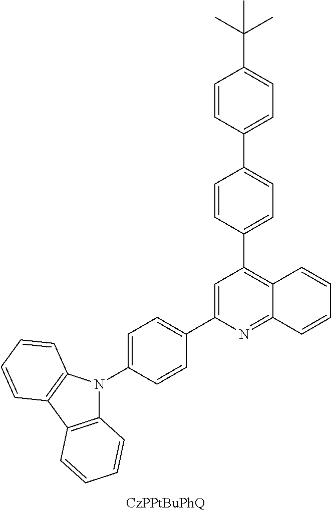 [SMILES: CC(C)(C)c1ccc(-c2ccc(-c3cc(-c4ccc(-n5c6ccccc6c6ccccc65)cc4)nc4ccccc34)cc2)cc1]

1-(4-(9H-carbazol-9-yl)phenyl)ethanone (285 mg, 1.00 mmol), 4-tert-butylphenyl-boronic (0.36 g, 2.00 mmol) and potassium carbonate (3.32 g, 24.00 mmol) were added into a single-neck flask. Into the flask was added with water (12 ml) and toluene (36 ml) and heated to a temperature of 60° C. to allow the solid dissolve completely. Then the flask was purged with nitrogen several times and quickly added with Pd(PPh₃)₄ (0.06 g, 0.05 mmol), purged with nitrogen several times again and the content in the flask was reacted at a temperature of 100° C. for 24 hours. When the reaction completed, the resultant mixture was extracted with ethyl acetate and water. The organic layer was dried with magnesium sulfate and then added with silica gel along with concentration. Finally, the resultant product was purified by column chromatography using hexane/ethyl acetate in volume ratio of 10:1 to obtain 501 mg of 9-(4-(4-(4′-(tert-butyl)-[1,1′-biphenyl]-4-yl)-quinolin-2-yl)phenyl)-9H-carbazol, yield=86.7%.

The NMR data of the product was as follows.

¹H NMR (400 MHz, CDCl₃, δ): 1.40 (s, 9H), 7.30 (dd, 2H, J=7.2, 7.6 Hz), 7.41-7.44 (m, 2H), 7.49-7.56 (m, 5H), 7.64-7.68 (m, 3H), 7.73-7.80 (m, 5H), 7.95 (s, 1H), 8.03 (d, 1H, J=8.4 Hz), 8.15 (d, 1H, J=7.6 Hz), 8.29 (d, 1H, J=8.4 Hz), 8.43 (d, 1H, J=8.4 Hz); ¹³C NMR (100 MHz, CDCl₃, δ): 31.4, 34.6, 109.8, 119.2, 1201, 120.3, 123.5, 125.8, 125.9, 126.0, 126.1, 126.6, 126.8, 127.2, 127.3, 129.1, 129.8, 130.0, 130.2, 136.9, 137.5, 138.7, 138.8, 140.7, 141.3, 148.9, 149.2, 150.8, 156.0; HRMS (EI, m/z): [M⁺] calcd for C₃₃H₂₁BrN₂, 578.2722. found, 578.2714.

### Preparation Example 7

### Preparation of 9-(4-(6-(4-(tert-butyl)phenyl)-4-phenyl-quinolin-2-yl)phenyl)-9H-carbazol (CzPPQtBuPh)

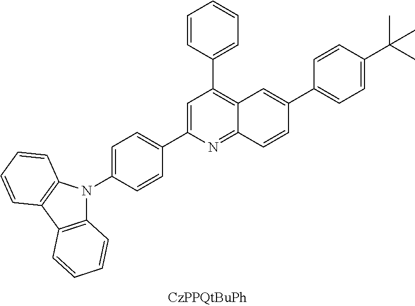 [SMILES: CC(C)(C)c1ccc(-c2ccc3nc(-c4ccc(-n5c6ccccc6c6ccccc65)cc4)cc(-c4ccccc4)c3c2)cc1]

1-(4-(9H-carbazol-9-yl)phenyl)ethanone (285 mg, 1.00 mmol), 4-tert-butylphenyl-boronic (0.36 g, 2.00 mmol) and potassium carbonate (3.32 g, 24.00 mmol) were added into a single-neck flask. Into the flask was added with water (12 ml) and toluene (36 ml) and heated to a temperature of 60° C. to allow the solid dissolve completely. Then the flask was purged with nitrogen several times and quickly added with Pd(PPh₃)₄ (0.06 g, 0.05 mmol), purged with nitrogen several times again and the content in the flask was reacted at a temperature of 100° C. for 24 hours. When the reaction completed, the resultant mixture was extracted with ethyl acetate and water. The organic layer was dried with magnesium sulfate and then added with silica gel along with concentration. Finally, the resultant product was purified by column chromatography using hexane/ethyl acetate in volume ratio of 10:1 to obtain 501 mg of 9-(4-(6-(4-(tert-butypphenyl)-4-phenylquinolin-2-ypphenyl)-9H-carbazol, yield=86.7%.

The NMR data of the product was as follows.

¹H NMR (400 MHz, CDCl₃, δ): 1.35 (s, 9H), 7.30 (dd, 2H, J=7.6, 7.2 Hz), 7.40-7.65 (m, 13H), 7.43 (d, 2H, J=7.6), 7.91 (s, 1H), 8.02 (d, 1H, J=8.8 Hz), 8.11 (s, 1H), 8.15 (d, 2H, J=7.6 Hz), 8.31 (d, 2H, J=8.4 Hz), 8.43 (d, 1H, J=7.6 Hz); ¹³C NMR (100 MHz, CDCl₃, δ): 31.3, 34.6, 109.9, 119.6, 1201, 1203, 123.2, 123.5, 125.8, 126.0, 126.1, 127.1, 127.3, 128.6, 128.7, 128.9, 129.4, 129.6, 130.5, 137.7, 138.4, 138.7, 139.2, 140.7, 148.2, 149.6, 150.8, 155.7; HRMS (EI, m/z): [M⁺] calcd for C₃₃H₂₁BrN₂, 578.2722. found, 578.2730.

### B. Energy Level and Thermal Stability of the Compounds Having Quinolyl and Carbazolyl Groups

The comparison of energy level and thermal stability of the compounds produced from Preparation Examples 1 to 7 with commonly used host material 4,4′-N,N-dicarbazole-biphenyl (CBP) was shown in Table 1. From Table 1, it is shown that CzPPCzQ and CzPPQCz exhibited better glass transition temperature and decomposition temperature.

TABLE 1
Energy level and thermal stability of the compounds having
quinolyl and carbazolyl groups

| | | | HOMO | LUMO | E_{g} | E_{T} |
|---|---|---|---|---|---|---|
| Compound | T_{g} (° C.) | T_{d} (° C.) | (eV) | (eV) | (eV) | (eV) |
| CzPPQ | 89 | 345 | 5.77 | 2.45 | 3.32 | 2.50 |
| CzPPCzQ | 145 | 419 | 5.79 | 2.50 | 3.29 | 2.77 |
| CzPPQCz | 146 | 421 | 5.83 | 2.71 | 3.12 | 2.38 |
| CzPPtBuPhQ | N/A | N/A | 5.83 | 2.58 | 3.25 | 2.39 |
| CzPPQtBuPh | N/A | N/A | 5.79 | 2.60 | 3.19 | 2.39 |
| CBP | 62 | 373 | 5.91 | 2.51 | 3.40 | 2.56 |

Note:
Tg = glass transition temperature, Td = decomposition temperature, N/A = non avaliable

### C. Structure of Organic Luminescent Diode Device

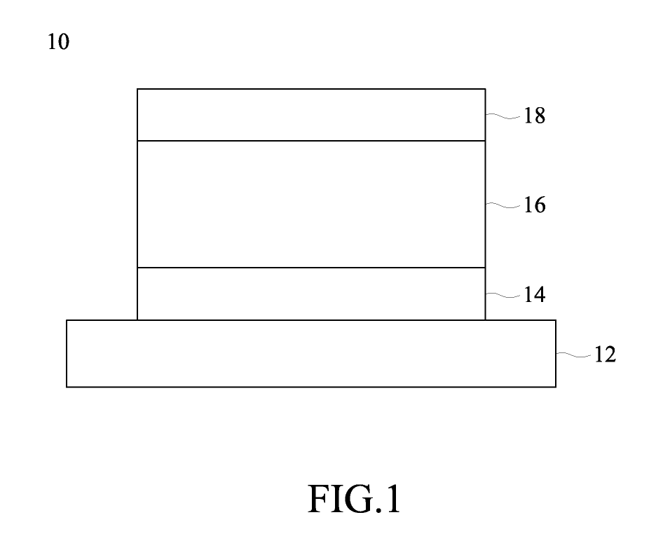

FIG. 1 is a schematic drawing showing an organic luminescent diode device containing the present compound according to an embodiment of the present disclosure. The organic luminescent diode device 10 comprises a substrate 12, a bottom electrode 14, an electroluminescent element 16, and a top electrode 18. The electroluminescent element 16 further comprises an emission layer containing the bipolar compound having quinolyl and carbazolyl groups of the present disclosure. The bipolar compound having quinolyl and carbazolyl groups could function as either a host emission material or a dopant. In the case, the bipolar compound serves as a host emission material in the host emission layer.

Moreover, the organic luminescent diode device 10 may optionally comprises a hole barrier layer, an exciton barrier layer, an electron barrier layer, and an electron injecting layer. Such layers are easily determined by those skilled in the art depending on the desired design.

Using the bipolar compound having quinolyl and carbazolyl groups in green, orange, and red organic luminescent diode and their luminescent effect are described as follows.

### Test Example 1

### Green Organic Luminescent Diode

The tested green organic luminescent diode has the following structure in which the number in the parentheses means the thickness in nm.

NPB(20)/TCTA(10)/7% Ir(ppy)₃:CzPPQanalogue(30)/BCP(10)/Alq(40)/LiF(1)

In the doped green organic luminescent diode, the substrate was made from ITO (indium tin oxide), the electrode to be tested was LiF/Al, the hole transport layer contained TCTA (4,4,4-tri(N-carbazolyl)triphenylamine) and NPB (N,N′-Bis-(naphthalen-1-yl)-N,N′-bis(phenyl)-benzidine); and the electron transport layer contained BAlq (Bis(2-methyl-8-quinolinolato-N1,O8)-(1,1′-Biphenyl-4-olato)-aluminum). In this Test Example, the bipolar compound having quinolyl and carbazolyl groups of the present disclosure was used as host material in the emission layer, and CBP (4,4′-Bis(9H-carbazol-9-yl)biphenyl) was used as a control. Dopant was added into various emission materials in the emission layer. In the green organic luminescent diode, the dopant was 7% Ir(ppy)₃ (tris(2-phenylpyridine)iridium (III)) and their luminescent efficiency are presented in Table 2.

TABLE 2
Luminescent efficiency of the present compound in green organic luminescent diode

| | V_{d} | ηₑₓₜ | L | η_{c} | ηₚ | λₑₘ | CIE, 8 V |
|---|---|---|---|---|---|---|---|
| Device | [V] | [%, V] | [cd/m², V] | [cd/A, V] | [lm/W, V] | [nm] | (x, y) |
| CzPPQ | 2.7 | 13.1, 4.0 | 100914, 15.0 | 50.0, 4.0 | 51.0, 3.0 | 516 | (0.28, 0.65) |
| CzPPCzQ | 3.0 | 16.0, 4.5 | 104983, 17.5 | 61.9, 4.5 | 51.5, 3.5 | 516 | (0.28, 0.65) |
| CzPPQCz | 2.9 | 1.6, 3.0 | 14923, 15.0 | 6.0, 3.0 | 6.3 3.0 | 518 | (0.30, 0.63) |
| CzPPtBuPhQ | 2.2 | 15.0, 2.5 | 77416, 16.0 | 58.5, 2.5 | 73.6, 2.5 | 514 | (0.29, 0.64) |
| CzPPQtBuPh | 3.2 | 0.24, 3.5 | 3055, 16.5 | 0.9, 3.5 | 0.9, 3.5 | 522 | (0.31, 0.61) |
| CBP | 2.7 | 13.1, 4.0 | 100914, 15.0 | 50.0, 4.0 | 51.0, 3.0 | 516 | (0.28, 0.65) |

Note:
V_{d}; driving voltage; ηₑₓₜ: external quantum efficiency; L: maximal lightness; η_{c}: current efficiency; ηₚ: energy efficiency; λₑₘ: emission wavelength

### Test Example 2

### Orange Organic Luminescent Diode

The tested orange organic luminescent diode has the following structure in which the number in the parentheses means the thickness in nm.

NPB(20)/TCTA(10)/4% Ir(pq)₃:CzPPQ analogue(30)/BCP(15)/Alq(50)/LiF(1)

The configuration and material used in each layers in the doped orange organic luminescent diode were similar to those in the Test Example 1 except that the dopant was 4% Ir(pq)₃ (tris(2-phenylquinoline)iridium (III)) and their luminescent efficiency are presented in Table 3.

TABLE 3
Luminescent efficiency of the present compound in orange organic luminescent diode

| | V_{d} | ηₑₓₜ | L | η_{c} | ηₚ | λₑₘ | CIE, 8 V |
|---|---|---|---|---|---|---|---|
| Device | [V] | [%, V] | [cd/m², V] | [cd/A, V] | [lm/W, V] | [nm] | (x, y) |
| CzPPQ | 3.0 | 25.6, 3.5 | 129885, 14.5 | 75.8, 3.5 | 68.1, 3.5 | 580 | (0.55, 0.45) |
| CzPPCzQ | 3.0 | 21.6, 3.5 | 144746, 16.5 | 59.4, 3.5 | 53.4, 3.5 | 586 | (0.56, 0.44) |
| CzPPQCz | 2.7 | 17.2, 4.0 | 120274, 17.0 | 51.2, 4.0 | 50.1, 3.0 | 582 | (0.55, 0.45) |
| CzPPtBuPhQ | 2.5 | 17.3, 3.0 | 84045, 15.0 | 47.4, 3.5 | 49.7, 3.5 | 584 | (0.56, 0.44) |
| CzPPQtBuPh | 2.6 | 15.1, 3.0 | 69878, 16.5 | 42.3, 3.0 | 44.3, 3.0 | 584 | (0.56, 0.44) |
| GH-PhCz | 2.8 | 25.8, 3.0 | 118075, 17.0 | 68.4, 3.0 | 71.7, 3.0 | 588 | (0.57, 0.43) |

Note:
V_{d}; driving voltage; ηₑₓₜ: external quantum efficiency; L: maximal lightness; η_{c}: current efficiency; ηₚ: energy efficiency; λₑₘ: emission wavelength

### Test Example 3

### Red Organic Luminescent Diode

The tested red organic luminescent diode has the following structure in which the number in the parentheses means the thickness in nm.

NPB(20)/TCTA(10)/7% Ir(piq)₃:CzPPQ analogue(30)/BCP(15)/Alq(50)/LiF(1)

The configuration and material used in each layers in the doped red organic luminescent diode were similar to those in the Test Example 1 except that the dopant was 7% Ir(piq)₃ (tris(2-phenyl-isoquinoline)iridium(III)) and their luminescent efficiency are presented in Table 4.

TABLE 4
Luminescent efficiency of the present compound in red organic luminescent diode

| | V_{d} | ηₑₓₜ | L | η_{c} | ηₚ | λₑₘ | CIE, 8 V |
|---|---|---|---|---|---|---|---|
| Device | [V] | [%, V] | [cd/m², V] | [cd/A, V] | [lm/W, V] | [nm] | (x, y) |
| CzPPQ | 2.9 | 19.3, 4.0 | 61485, 14.5 | 24.8, 4.0 | 24.4, 3.0 | 620 | (0.67, 0.33) |
| CzPPCzQ | 3.0 | 21.5, 4.5 | 68384, 16.5 | 27.5, 4.5 | 24.1, 3.5 | 620 | (0.67, 0.33) |
| CzPPQCz | 2.2 | 17.5, 2.5 | 48967, 14.5 | 24.8, 2.5 | 31.3, 2.5 | 618 | (0.66, 0.34) |
| CzPPtBuPhQ | 2.6 | 15.0, 3.0 | 38130, 14.5 | 20.3, 3.0 | 21.3, 3.0 | 618 | (0.66, 0.34) |
| CzPPQtBuPh | 2.9 | 19.3, 4.0 | 61485, 14.5 | 24.8, 4.0 | 24.4, 3.0 | 620 | (0.67, 0.33) |
| CBP | 3.1 | 18.2, 5.0 | 56041, 15.0 | 24.6, 5.0 | 21.5, 3.5 | 620 | (0.66, 0.34) |

Note:
V_{d}; driving voltage; ηₑₓₜ: external quantum efficiency; L: maximal lightness; η_{c}: current efficiency; ηₚ: energy efficiency; λₑₘ: emission wavelength

### Test Example 4

### Green Organic Luminescent Diode Adding with Hole Injection Material NPNPB

The tested green organic luminescent diode has the following structure in which the number in the parentheses means the thickness in nm.

NPNPB(60)/NPB(10)/TCTA(10)/7% Ir(ppy)₃:CzPPQ analogue(30)/BAlq(30)/LiF(1)

The configuration and material used in each layers in the doped green organic luminescent diode were similar to those in the Test Example 1 except that it further included hole injection material NPNPB and their luminescent efficiency are presented in Tables 5-1 and 5-2.

TABLE 5-1
Luminescent efficiency of the present compound in green organic luminescent diode

| | L, 10 V | ηₑₓₜ | η_{c}, 10 V | λₑₘ, 8 V | FWHM | CIE, 8 V | T75 @ 500 |
|---|---|---|---|---|---|---|---|
| Device | [cd/m²] | [%, 10 V] | [cd/A] | [nm] | [nm] | (x, y) | nits (h) |
| CzPPQ | 13614 | 6.70 | 25.05 | 514 | 54 | (0.25, 0.66) | 46 |
| CzPPCzQ | 8297 | 11.56 | 44.73 | 516 | 60 | (0.27, 0.65) | 1035 |
| CzPPQCz | 82 | 1.37 | 5.21 | 522 | 72 | (0.32, 0.61) | 4 |
| CzPPtBuPhQ | 36890 | 3.87 | 14.58 | 514 | 56 | (0.26, 0.66) | 214 |
| CzPPQtBuPh | 929 | 0.14 | 0.54 | 516 | 62 | (0.29, 0.63) | 6 |
| CBP | 7819 | 13.9 | 50.4 | 510 | 54 | (0.24, 0.62) | 2331 |

Note:
FWHM: full width at half maximum; T₇₅ @ 500 nits (h): time required when the brightness is reduced 25% relative to initial brightness at 500 nit

TABLE 5-2
Luminescent efficiency of the present compound in green organic
luminescent diode

| | | Current | | | |
|---|---|---|---|---|---|
| | | Density | ηₑₓₜ | η_{c} | ηₚ |
| | V, | [mA/cm², | [%, | [cd/A, | [lm/W, |
| Device | 500 nits | 500 nits] | 500 nits] | 500 nits] | 500 nits] |
| CzPPQ | 5.7 | 1.451 | 9.27 | 34.64 | 19.17 |
| CzPPCzQ | 6.2 | 0.820 | 15.79 | 61.09 | 31.23 |
| CzPPQCz | 12.1 | 10.922 | 1.21 | 4.58 | 1.19 |
| CzPPtBuPhQ | 3.7 | 1.273 | 10.64 | 40.07 | 34.31 |
| CzPPQtBuPh | 7.8 | 84.53 | 0.16 | 0.59 | 0.23 |
| CBP | 6.9 | 1.213 | 11.35 | 41.08 | 18.53 |

Note:
ηₑₓₜ: external quantum efficiency;
η_{c}: current efficiency;
ηₚ: energy efficiency

### Test Example 5

### Orange Organic Luminescent Diode Adding with Hole Injection Material NPNPB

The tested orange organic luminescent diode has the following structure in which the number in the parentheses means the thickness in nm.

NPNPB(60)/NPB(10)/TCTA(10)/4% Ir(pq)₃:CzPPQ analogue(30)/BAlq(30)/LiF(1)

The configuration and material used in each layers in the doped orange organic luminescent diode were similar to those in the Test Example 2 except that it further included hole injection material NPNPB and their luminescent efficiency are presented in Tables 6-1 and 6-2.

TABLE 6-1
Luminescent efficiency of the present compound in orange organic luminescent diode

| | L, 10 V | ηₑₓₜ | η_{c}, 10 V | λₑₘ, 8 V | FWHM | CIE, 8 V | T75 @ 500 |
|---|---|---|---|---|---|---|---|
| Device | [cd/m²] | [%, 10 V] | [cd/A] | [nm] | [nm] | (x, y) | nits (h) |
| CzPPQ | 5379 | 13.18 | 39.78 | 580 | 64 | (0.54, 0.46) | 6095 |
| CzPPCzQ | 4517 | 17.58 | 52.53 | 582 | 66 | (0.55, 0.45) | 6106 |
| CzPPQCz | 8463 | 8.30 | 24.78 | 582 | 66 | (0.54, 0.45) | 289 |
| CzPPtBuPhQ | 5293 | 8.91 | 26.86 | 580 | 64 | (0.54, 0.46) | 5861 |
| CzPPQtBuPh | 6403 | 6.28 | 18.63 | 580 | 64 | (0.55, 0.45) | 635 |
| CBP | 7082 | 12.2 | 37.1 | 580 | 62 | (0.54, 0.46) | 2415 |

Note:
FWHM: full width at half maximum; T₇₅ @ 500 nits (h): time required when the brightness is reduced 25% relative to initial brightness at 500 nit

TABLE 6-2
Luminescent efficiency of the present compound in orange organic
luminescent diode

| | | Current | | | |
|---|---|---|---|---|---|
| | | Density | ηₑₓₜ | η_{c} | ηₚ |
| | V, | [mA/cm², | [%, | [cd/A, | [lm/W, |
| Device | 500 nits | 500 nits] | 500 nits] | 500 nits] | 500 nits] |
| CzPPQ | 6.5 | 2.050 | 8.05 | 24.31 | 11.81 |
| CzPPCzQ | 6.9 | 1.026 | 16.24 | 48.53 | 22.16 |
| CzPPQCz | 6.2 | 2.467 | 6.72 | 20.04 | 10.13 |
| CzPPtBuPhQ | 6.2 | 4.078 | 4.03 | 12.15 | 6.23 |
| CzPPQtBuPh | 6.5 | 8.069 | 2.082 | 6.17 | 2.97 |
| CBP | 6.7 | 1.156 | 14.14 | 43.14 | 20.32 |

Note:
ηₑₓₜ: external quantum efficiency;
η_{c}: current efficiency;
ηₚ: energy efficiency

### Test Example 6

### Red Organic Luminescent Diode Adding with Hole Injection Material NPNPB

The tested red organic luminescent diode has the following structure in which the number in the parentheses means the thickness in nm.

NPNPB(60)/NPB(10)/TCTA(10)/4% Ir(piq)₃:CzPPQ analogue(30)/BAlq(30)/LiF(1)

The configuration and material used in each layers in the doped red organic luminescent diode were similar to those in the Test Example 3 except that it further included hole injection material NPNPB and their luminescent efficiency are presented in Tables 7-1 and 7-2.

TABLE 7-1
Luminescent efficiency of the present compound in red organic luminescent diode

| | L, 10 V | ηₑₓₜ | η_{c}, 10 V | λₑₘ, 8 V | FWHM | CIE, 8 V | T75 @ 500 |
|---|---|---|---|---|---|---|---|
| Device | [cd/m²] | [%, 10 V] | [cd/A] | [nm] | [nm] | (x, y) | nits (h) |
| CzPPQ | 3155 | 12.99 | 18.39 | 616 | 52 | (0.66, 0.34) | 771 |
| CzPPCzQ | 5865 | 12.76 | 17.55 | 618 | 50 | (0.66, 0.33) | 486 |
| CzPPQCz | 1425 | 10.11 | 13.04 | 618 | 54 | (0.66, 0.33) | 246 |
| CzPPtBuPhQ | 1262 | 11.00 | 15.36 | 616 | 50 | (0.66, 0.34) | 1009 |
| CzPPQtBuPh | 1425 | 8.40 | 11.19 | 618 | 52 | (0.66, 0.34) | 185 |
| CBP | 1027 | 1.6 | 0.9 | 620 | 52 | (0.62, 0.33) | 97 |

Note:
FWHM: full width at half maximum; T₇₅ @ 500 nits (h): time required when the brightness is reduced 25% relative to initial brightness at 500 nit

TABLE 7-2
Luminescent efficiency of the present compound in red organic
luminescent diode

| | | Current | | | |
|---|---|---|---|---|---|
| | | Density | ηₑₓₜ | η_{c} | ηₚ |
| | V, | [mA/cm², | [%, | [cd/A, | [lm/W, |
| Device | 500 nits | 500 nits] | 500 nits] | 500 nits] | 500 nits] |
| CzPPQ | 7.5 | 2.260 | 15.64 | 22.15 | 9.23 |
| CzPPCzQ | 6.7 | 8.746 | 4.12 | 5.58 | 2.58 |
| CzPPQCz | 8.5 | 3.522 | 11.00 | 14.20 | 5.27 |
| CzPPtBuPhQ | 7.3 | 2.767 | 12.96 | 18.09 | 7.77 |
| CzPPQtBuPh | 8.6 | 3.930 | 9.4 | 12.52 | 4.53 |
| CBP | 13.3 | 8.396 | 4.69 | 5.97 | 1.41 |

Note:
ηₑₓₜ: external quantum efficiency;
η_{c}: current efficiency;
ηₚ: energy efficiency

### D. Determination of Life Time for Luminescent Diode Device Containing the Present Compound

Luminescent diode devices A, E, H, and I were determined their life time wherein each devices has the following structure in which the number in the parentheses means the thickness in nm. In these devices, Devices A and I are the present device using the present compound as the emission material and Devices E and H are control group using conventional BCP as the emission material.

Device A: ITO/NPB(20 nm)/TCTA(10 nm)/CzPPQ: Ir(piq)₃(4 wt %)(30 nm)/BCP(15 nm)/Alq₃(50 nm)/LiF(1 nm)/Al(100 nm)

Device E: ITO/NPB(20 nm)/TCTA(10 nm)/CBP: Ir(piq)₃(4 wt %)(30 nm)/BCP(15 nm)/Alq₃(50 nm)/LiF(1 nm)/Al(100 nm)

Device H: ITO/NPB(20 nm)/TCTA(10 nm)/CBP: Ir(pq)₃(4 wt %)(30 nm)/BCP(15 nm)/Alq₃(50 nm)/LiF(1 nm)/Al(100 nm)

Device I: ITO/NPB(20 nm)/TCTA(10 nm)/CzPPQ: Ir(pq)₃(4 wt %)(30 nm)/BCP(15 nm)/Alq₃(50 nm)/LiF(1 nm)/Al(100 nm)

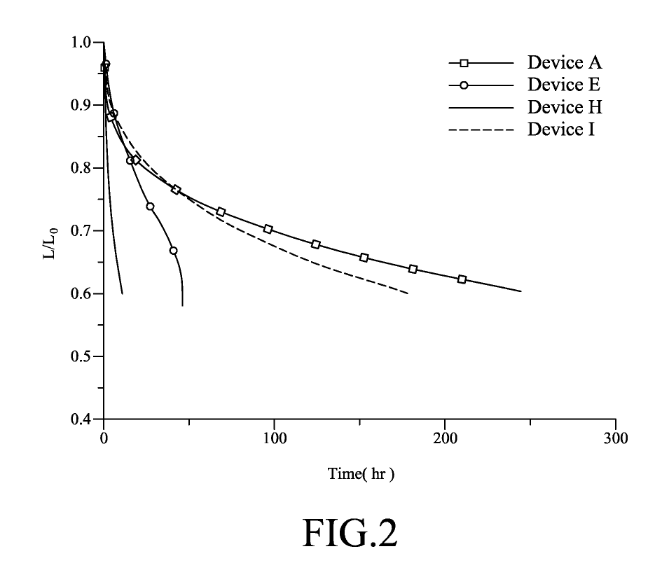

The decadence of luminescent efficiency with time for Device A, E, H, and I are shown in FIG. 2. From FIG. 2, it is known that the Device A and Device I using CzPPQ as emission material exhibit slower decadence than Device E an H using CBP as emission material.

Moreover, Device A, E, H, and I were determined their life time when the brightness was reduced 40% (T60) with an electroluminescence of 500 candela per square meter (cd/m²). The results are shown in Table 8. From Table 8, it shown that the life time for Device A and Device I was 8991 and 19111 hours, respectively, which were far higher than the control Device E and H.

TABLE 8
Life time for luminescent diode devices

| Device | Emission material | T60 @ 500 cd/m² (hr) |
|---|---|---|
| A | CzPPQ: Ir(piq)₃ (4 wt %) | 8991 |
| E | CBP: Ir(piq)₃ (4 wt %) | 1672 |
| H | CBP: Ir(pq)₃ (4 wt %) | 1110 |
| I | CzPPQ: Ir(pq)₃ (4 wt %) | 19111 |

From the above, it is evident that the bipolar compound having quinolyl and carbazolyl groups of the present disclosure enhances the hole transport efficiency when using as emission material. While the present compound is used as host material in emission layer, it enhances the luminescent efficiency and electric property, and prolongs the life time of the OLED. Therefore, the bipolar compound of the present disclosure is potentially used as a substitute for current host material and can be used for producing OLED device having excellent luminescent efficiency.

While the disclosure has been described in detail, modifications within the spirit and scope of the disclosure will be readily apparent to those of skill in the art. In addition, it should be understood that aspects of the disclosure and portions of various embodiments and various features recited herein and/or in the appended claims may be combined or interchanged either in whole or in part. In the foregoing descriptions of the various embodiments, those embodiments which refer to another embodiment may be appropriately combined with one or more other embodiments, as will be appreciated by one of skill in the art. Furthermore, those of ordinary skill in the art will appreciate that the foregoing description is by way of example only, and is not intended to limit the disclosure.

1. A bipolar compound represented by the following formula (I): 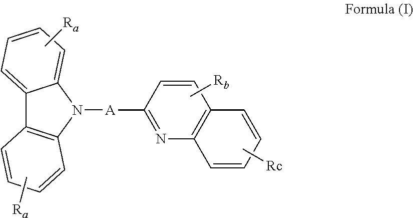
wherein A represents phenyl, biphenyl, or terphenyl group; and
Rₐ, R_{b}, and R_{c} are independently selected from a group consisting of hydrogen, halo, cyano, trifluoromethyl, amino, C₁-C₁₀ alkyl, C₂-C₁₀ alkenyl, C₂-C₁₀ alkynyl, C₃-C₂₀ cycloalkyl, C₃-C₂₀ cycloalkenyl, C₁-C₂₀ heterocyclic alkyl, C₁-C₂₀ hetercyclic alkenyl, aryl, and heteroaryl group.

2. The bipolar compound according to claim 1, wherein said A is further substituted by at least one substituent selected from a group consisting of hydrogen, halo, cyano, trifluoromethyl, amino, C₁-C₁₀ alkyl, C₂-C₁₀ alkenyl, C₂-C₁₀ alkynyl, C₃-C₂₀ cycloalkyl, C₃-C₂₀ cycloalkenyl, C₁-C₂₀ heterocyclic alkyl, C₁-C₂₀ hetercyclic alkenyl, aryl, and heteroaryl group.

3. The bipolar compound according to claim 1, wherein said aryl is phenyl group or substituted phenyl group.

4. The bipolar compound according to claim 2, wherein said aryl is phenyl group or substituted phenyl group.

5. The bipolar compound according to claim 1, wherein said heteroaryl is carbazolyl group.

6. The bipolar compound according to claim 2, wherein said heteroaryl is carbazolyl group.

7. The bipolar compound according to claim 1, wherein said Rₐ and R_{c} are different by each other.

8. The bipolar compound according to claim 1, wherein said Rₐ and R_{c} are independently selected from the following groups: 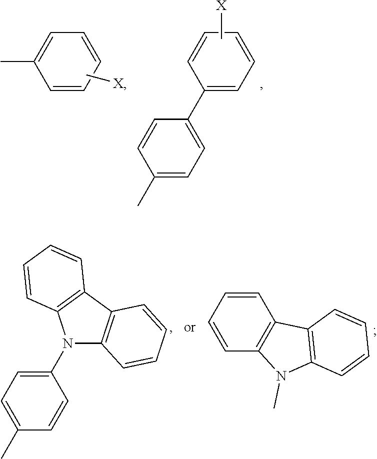
wherein X represents hydrogen, halo, cyano, trifluoromethyl, amino, or C₁-C₁₀ alkyl group.

9. An organic luminescent diode device comprising:
a pair of electrodes; and
an electroluminescent element, disposed between said pair of electrodes;
wherein said electroluminescent element comprises a compound having the following formula (I): 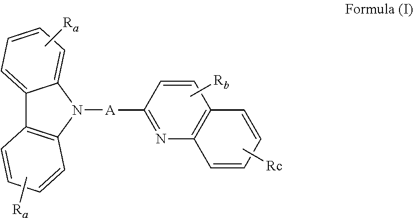
wherein A represents phenyl, biphenyl, or terphenyl group;
Rₐ, R_{b}, and R_{c} are independently selected from a group consisting of hydrogen, halo, cyano, trifluoromethyl, amino, C₁-C₁₀ alkyl, C₂-C₁₀ alkenyl, C₂-C₁₀ alkynyl, C₃-C₂₀ cycloalkyl, C₃-C₂₀ cycloalkenyl, C₁-C₂₀ heterocyclic alkyl, C₁-C₂₀ hetercyclic alkenyl, aryl, and heteroaryl group.

10. An organic electroluminescent diode device comprising:
a pair of electrodes; and
an electroluminescent element disposed between said pair of electrodes;
wherein said electroluminescent element comprises an emission layer and said emission layer comprises a dopant material and a compound having the following formula (I) as a host material: 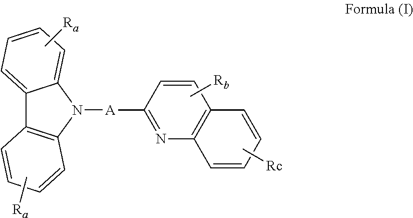
wherein A represents phenyl, biphenyl, or terphenyl group;
Rₐ, R_{b}, and R_{c} are independently selected from a group consisting of hydrogen, halo, cyano, trifluoromethyl, amino, C₁-C₁₀ alkyl, C₂-C₁₀ alkenyl, C₂-C₁₀ alkynyl, C₃-C₂₀ cycloalkyl, C₃-C₂₀ cycloalkenyl, C₁-C₂₀ heterocyclic alkyl, C₁-C₂₀ hetercyclic alkenyl, aryl, and heteroaryl group.

11. The organic electroluminescent diode device according to claim 8, wherein said dopant material comprises a green emitting dopant material in an amount of from 0 to 10 wt. %.

12. The organic electroluminescent diode device according to claim 9, wherein said green emitting dopant material is tris(2-phenylpyridine)iridium (Ir(ppy)₃).

13. The organic electroluminescent diode device according to claim 8, wherein said dopant material comprises an orange emitting dopant material in an amount of from 0 to 10 wt. %.

14. The organic electroluminescent diode device according to claim 11, wherein said orange emitting dopant material is tris(2-phenylquinoline)iridium (Ir(pq)₃).

15. The organic electroluminescent diode device according to claim 8, wherein said dopant material comprises an red emitting dopant material in an amount of from 0 to 10 wt. %.

16. The organic electroluminescent diode device according to claim 13, wherein said red emitting dopant material is tris(2-phenyl-isoquinoline)iridium (Ir(piq)₃).
